(19) United States
(12) Patent Application Publication
(10) Pub. No.: US 2025/0149481 A1
(43) Pub. Date: May 8, 2025

(54) SEMICONDUCTOR PACKAGE

(71) Applicant: Samsung Electronics Co., Ltd., Suwon-si (KR)

(72) Inventor: Youngbae Kim, Suwon-si (KR)

(21) Appl. No.: 18/829,546

(22) Filed: Sep. 10, 2024

(30) Foreign Application Priority Data
Nov. 7, 2023 (KR) 10-2023-0152333

(51) Int. Cl. H01L 23/00; H01L 23/48; H01L 25/18; H05K 1/18; H10B 80/00

(52) U.S. Cl. CPC H01L 24/06; H01L 24/05; H01L 24/16; H01L 24/32; H01L 24/73; H01L 23/481; H01L 24/03; H01L 25/18; H01L 2224/0332; H01L 2224/03462; H01L 2224/0517; H01L 2224/05557; H01L 2224/05582; H01L 2224/0603; H01L 2224/06131; H01L 2224/0651; H01L 2224/16145; H01L 2224/16225; H01L 2224/32145; H01L 2224/32225; H01L 2224/73204; H01L 2225/06513; H01L 2225/06517; H01L 2225/06544; H01L 2225/06589; H01L 2924/1431; H01L 2924/1436; H01L 2924/1815; H05K 1/181; H10B 80/00

(57) ABSTRACT

A semiconductor package includes a buffer die, memory dies sequentially stacked on the buffer die, a bonding layer that extends between ones of the memory dies and configured to bond the memory dies with each other, and a molding member on the buffer die and covering or overlapping sidewalls of the memory dies. Each of the memory dies includes a substrate having first and second surfaces opposite to each other in a vertical direction substantially perpendicular to an upper surface of the buffer die, and a first signal pad and a test pad structure beneath the first surface of the substrate. The test pad structure includes a test pad and a first conductive pattern stacked in the vertical direction on the first surface of the substrate. The first conductive pattern has an uneven lower surface.

### CROSS-REFERENCE TO RELATED APPLICATION

This application claims priority under 35 U.S.C. § 119 to Korean Patent Application No. 10-2023-0152333, filed on Nov. 7, 2023 in the Korean Intellectual Property Office (KIPO), the contents of which are herein incorporated by reference in their entirety.

### BACKGROUND

Example embodiments relate to a semiconductor package. More particularly, example embodiments relate to a semiconductor package including a plurality of stacked chips.

A high bandwidth memory (HBM) package includes memory chips vertically stacked on a logic chip, which are bonded with each other by a bonding layer. The bonding state of the memory chips is important in order that the HBM package may have good performance, and thus it is needed to study a method of enhancing the bonding state of the memory chips.

### SUMMARY

Example embodiments provide a semiconductor package having enhanced electrical characteristics.

According to example embodiments, there is provided a semiconductor package. The semiconductor package may include a buffer die, memory dies sequentially stacked on the buffer die, a bonding layer that extends between ones of the memory dies and the bonding layer is configured to bond ones of the memory dies with each other, and a molding member on the buffer die and on sidewalls of the memory dies. Each of the memory dies may include a substrate having first and second surfaces opposite to each other in a vertical direction substantially perpendicular to an upper surface of the buffer die, and a first signal pad and a test pad structure on the first surface of the substrate. The test pad structure may include a test pad and a first conductive pattern stacked in the vertical direction on the first surface of the substrate. The first conductive pattern may have an uneven surface facing the substrate.

According to example embodiments, there is provided a semiconductor package. The semiconductor package may include a buffer die, memory dies sequentially stacked on the buffer die, a conductive connection member between the memory dies and including a first conductive pattern and a second conductive pattern stacked in a vertical direction substantially perpendicular to an upper surface of the buffer die and including different materials from each other, a bonding layer between the memory dies and the bonding layer is configured to bond ones of the memory dies with each other, and a molding member on the buffer die and on sidewalls of the memory dies. Each of the memory dies may include a substrate having first and second surfaces opposite to each other in the vertical direction, and a signal pad and a test pad structure on the first surface of the substrate. The test pad structure may include a test pad and a third conductive pattern stacked in the vertical direction on the first surface of the substrate. The signal pad may contact the first conductive pattern of the conductive connection member, and a distance from the substrate to a lowermost surface of the third conductive pattern may be less than a distance from the substrate toa lower surface of the first conductive pattern.

According to example embodiments, there is provided a semiconductor package. The semiconductor package may include a first die, a second die on the first die, a conductive connection member between the first and second dies and including first and second conductive patterns stacked in a vertical direction substantially perpendicular to an upper surface of the first die and including different materials from each other, and a bonding layer between the first and second dies and the bonding layer is configured to bond the first and second dies with each other and is on sidewalls of the conductive connection member. The first die may include a first substrate having first and second surfaces opposite to each other in the vertical direction. The second die may include a second substrate having first and second surfaces opposite to each other in the vertical direction, and a signal pad and a test pad structure on the first surface of the second substrate. The test pad structure may include a test pad and a third conductive pattern stacked in the vertical direction on the first surface of the second substrate. The third conductive pattern may have an uneven lower surface. The signal pad may contact the conductive connection member and the first conductive pattern, and a distance from the substrate to a lowermost surface of the third conductive pattern may be less than a distance from the substrate to a lower surface of the first conductive pattern.

The semiconductor package in accordance with example embodiments may include a plurality of semiconductor chips sequentially stacked in the vertical direction, and there is no gap between the bonding layer and each of the semiconductor chips. Thus, the semiconductor chips may be well bonded with each other, and the semiconductor package may have enhanced electrical characteristics.

### BRIEF DESCRIPTION OF THE DRAWINGS

FIG. 1 is a cross-sectional view illustrating an electronic device in accordance with example embodiments.

FIG. 2 is a cross-sectional view illustrating an HBM package in accordance with example embodiments, and FIG. 3 is an enlarged cross-sectional view of a region Y in FIG. 2.

FIG. 4 is a plan view illustrating layouts of third and fourth conductive pads of each semiconductor chip included in the HBM package.

FIGS. 5 to 15 are cross-sectional views illustrating a method of manufacturing an HBM package in accordance with example embodiments.

### DETAILED DESCRIPTION

Hereinafter, example embodiments will be explained in detail with reference to the accompanying drawings. Hereinafter, a direction substantially parallel to an upper surface of a substrate or a wafer may be referred to as a horizontal direction, and a direction substantially perpendicular to the upper surface of the substrate or the wafer may be referred to as a vertical direction.

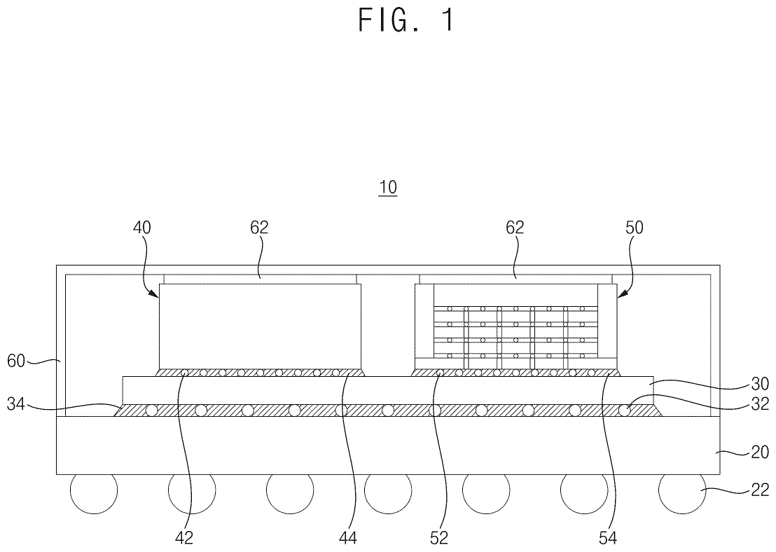

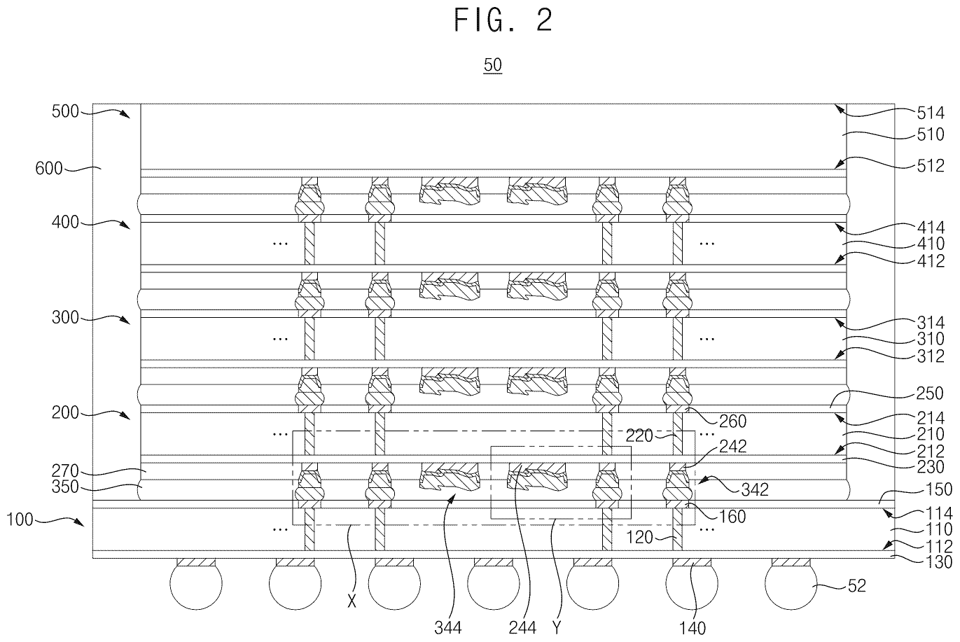

FIG. 1 is a cross-sectional view illustrating an electronic device in accordance with example embodiments.

Referring to FIG. 1, an electronic device 10 may include a package substrate 20, an interposer 30, a first semiconductor device 40 and a second semiconductor device 50. The electronic device 10 may further include first, second and third underfill members 34, 44 and 54, a heat slug 60 and a heat dissipation member 62.

In example embodiments, the electronic device 10 may be a memory module having a 2.5 D package structure, and thus may include the interposer 30 for electrically connecting the first and second semiconductor devices 40 and 50 to each other.

In example embodiments, the first semiconductor device 40 may include a logic device, and the second semiconductor device 50 may include a memory device. The logic device may be an application-specific integrated circuit (ASIC) chip including, e.g., a central processing unit (CPU), a graphics processing unit (GPU), a micro-processor, a micro-controller, an application processor (AP), a digital signal processing core, etc. The memory device may include a semiconductor package such as an HBM device.

In example embodiments, the package substrate 20 may have an upper surface and a lower surface opposite to each other in the vertical direction. For example, the package substrate 20 may be a printed circuit board (PCB). The printed circuit board may be a multi-layer circuit board having various circuits therein.

The interposer 30 may be disposed on the package substrate 20. The interposer 30 may be mounted on the package substrate 20 through a second conductive connection member 32. In example embodiments, a planar area of the interposer 30 may be smaller than a planar area of the package substrate 20. The interposer 30 may be disposed within an area of the package substrate 20 in a plan view.

The interposer 30 may be a silicon interposer or a redistribution interposer having a plurality of wirings therein. The first semiconductor device 40 and the second semiconductor device 50 may be connected to each other through the wirings in the interposer 30 or electrically connected to the package substrate 20 through the second conductive connection member 32. The second conductive connection member 32 may include, e.g., a micro-bump. The silicon interposer may provide a high-density interconnection between the first and second semiconductor devices 40 and 50.

The first semiconductor device 40 may be disposed on the interposer 30. The first semiconductor device 40 may be mounted on the interposer 30 by a flip chip bonding method. In this case, the first semiconductor device 40 may be mounted on the interposer 30 such that an active surface on which conductive pads are formed may face downwardly toward the interposer 30. The conductive pads of the first semiconductor device 40 may be electrically connected to conductive pads of the interposer 30 through a third conductive connection member 42. For example, third conductive connection member 42 may include, e.g., a micro-bump.

In some embodiments, the first semiconductor device 40 may be mounted on the interposer 30 by a wire bonding method, and in this case, the active surface of the first semiconductor device 40 may face upwardly.

The second semiconductor device 50 may be disposed on the interposer 30, and may be spaced apart from the first semiconductor device 40 in the horizontal direction. The second semiconductor device 50 may be mounted on the interposer 30 by a flip chip bonding method. In this case, conductive pads of the second semiconductor device 50 may be electrically connected to conductive pads of the interposer 30 by a fourth conductive connection member 52. For example, the fourth conductive connection member 52 may include, e.g., a micro-bump. In example embodiments, each of the third and fourth conductive connection members 42 and 52 may have a size smaller than that of the second conductive connection member 32, and the sizes of the third and fourth conductive connection members 42 and 52 may be the same as or different from each other.

Although a single first semiconductor device 40 and a single second semiconductor device 50 are disposed on the interposer 30, the inventive concept may not be limited thereto, and a plurality of first semiconductor devices 40 and/or a plurality of second conductive devices 50 may be disposed on the interposer 30.

In example embodiments, the first underfill member 34 may fill a space between the interposer 30 and the package substrate 20, and the second and third underfill members 44 and 54 may fill a space between the first semiconductor device 40 and the interposer 30 and a space between the second semiconductor device 50 and the interposer 30, respectively.

The first to third underfill members 34, 44 and 54 may include a material having a relatively high fluidity to effectively fill a small space between the first and second semiconductor devices 40 and 50 and the interposer 30 and a small space between the interposer 30 and the package substrate 20. For example, each of the first and second underfill members 34, 44 and 54 may include an adhesive that includes an epoxy material.

The second semiconductor device 50 may include a buffer die and a plurality of memory dies (chips) sequentially stacked on the buffer die. The buffer die and the memory dies may be electrically connected to each other by through silicon vias (TSVs), and the TSVs may be electrically connected to each other by conductive connection members. The buffer die and the memory dies may communicate data signals and control signals by the TSVs.

In example embodiments, the heat slug 60 may cover or overlap the package substrate 20 to thermally contact the first and second semiconductor devices 40 and 50. The heat slug 60 may thermally conduct heat from the first and second semiconductor devices 40 and 50. The heat dissipation member 62 may be disposed on an upper surface of each of the first and second semiconductor devices 40 and 50, and may include, e.g., thermal interface material (TIM). The heat slug 60 may thermally contact the first and second semiconductor devices 40 and 50 via the heat dissipation member 62.

A conductive pad may be formed at a lower portion of the package substrate 20, and a first conductive connection member 22 may be disposed beneath the conductive pad. In example embodiments, a plurality of first conductive connection members 22 may be spaced apart from each other in the horizontal direction. The first conductive connection member 22 may be, e.g., a solder ball. In example embodiments, the first conductive connection member 22 may be larger (i.e., have a greater width) than the second conductive connection member 32. The electronic device 10 may be mounted on a module board via the first conductive connection members 22 to form a memory module.

Hereinafter, the second semiconductor device 50 shown in FIG. 1, that is, an HBM package is described.

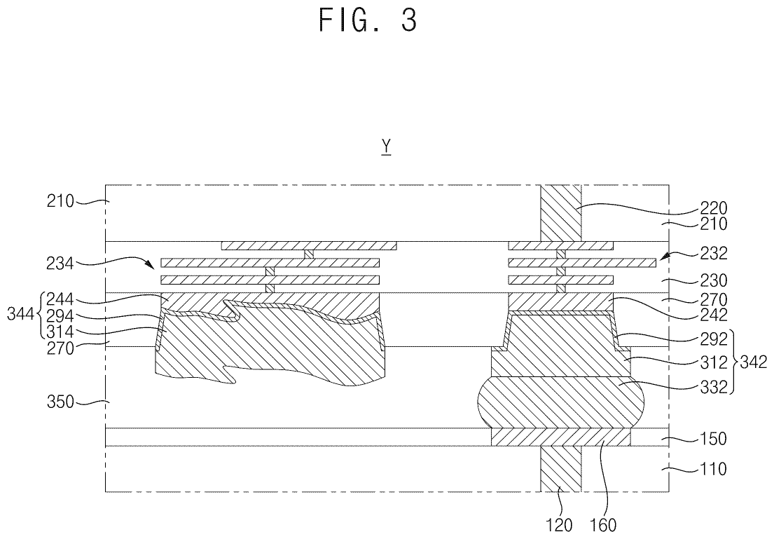

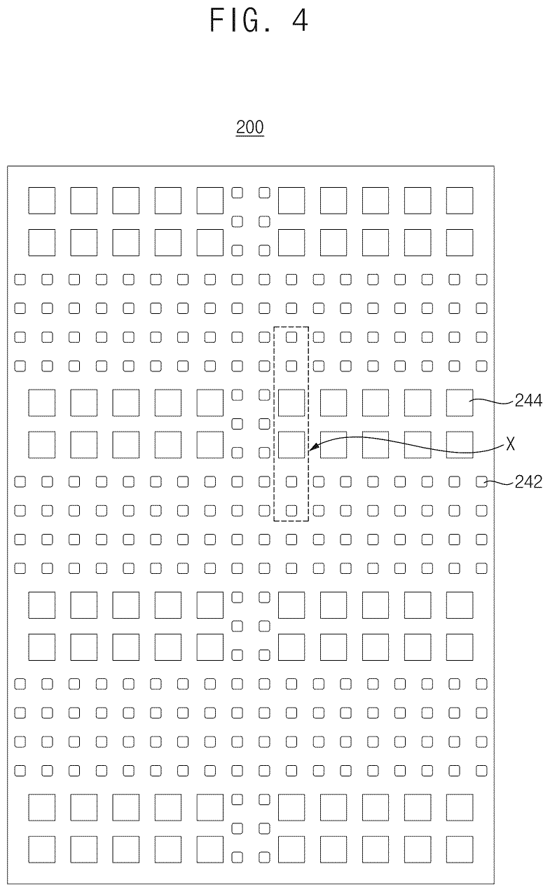

FIG. 2 is a cross-sectional view illustrating an HBM package in accordance with example embodiments, and FIG. 3 is an enlarged cross-sectional view of a region Y in FIG. 2. FIG. 4 is a plan view illustrating layouts of third and fourth conductive pads 242 and 244 of each semiconductor chip included in the HBM package. A region X of FIG. 4 corresponds to a region X of FIG. 2.

Referring to FIGS. 2 to 4, an HBM package 50 may include a first semiconductor chip 100, second, third, fourth and fifth semiconductor chips 200, 300, 400 and 500 sequentially stacked on the first semiconductor chip 100, a bonding layer 350 between the first to fifth semiconductor chips 100, 200, 300, 400 and 500, and a molding member 600 covering, on, or overlapping sidewalls of the second to fifth semiconductor chips 200, 300, 400 and 500 on the first semiconductor chip 100.

FIG. 2 shows the HBM package 50 includes five semiconductor chips 100, 200, 300, 400 and 500 stacked in the vertical direction, however, the inventive concept may not be limited thereto, and may include a plurality of semiconductor chips.

In example embodiments, the first semiconductor chip 100 may be a buffer die, and may include a logic device such as a controller. Each of the second to fifth semiconductor chips 200, 300, 400 and 500 may be a core die, and may include a volatile memory device such as a DRAM device, an SRAM device, etc., or a non-volatile memory device such as a flash memory device, an EEPROM device, etc.

The first semiconductor chip 100 may include a first substrate 110 having first and second surfaces 112 and 114 opposite to each other in the vertical direction that is perpendicular to first and second surfaces 112 and 114 of the first substrate 110, a first through electrode 120 extending through the first substrate 110, a first insulating interlayer and a second insulating interlayer 130 sequentially stacked in the vertical direction beneath the first surface 112 of the first substrate 110, a first conductive pad 140 beneath the second insulating interlayer 130, a third insulating interlayer 150 on the second surface 114 of the first substrate 110, and a second conductive pad 160 extending through the third insulating interlayer 150.

The first substrate 110 may include a semiconductor material, e.g., silicon, germanium, silicon-germanium, etc., or a III-V group compound semiconductor, e.g., GaP, GaAs, GaSb, etc. In example embodiments, the first substrate 110 may be a silicon-on-insulator (SOI) substrate or a germanium-on-insulator (GOI) substrate.

A circuit device, e.g., a logic device may be formed beneath the first surface 112 of the first substrate 110. The circuit device may include circuit patterns, e.g., transistors, capacitors, wiring structures, etc., which may be covered or overlapped by the first insulating interlayer.

The second insulating interlayer 130 may contain a first wiring structure therein. The first wiring structure may include, e.g., wirings, vias, etc.

The first conductive pad 140 may be disposed beneath the second insulating interlayer 130, and may contact the first wiring structure to be electrically connected thereto. In example embodiments, a plurality of first conductive pads 140 may be spaced apart from each other in the horizontal direction.

The first through electrode 120 may extend in the first substrate 110 in the vertical direction, and a plurality of first through electrodes may be spaced apart from each other in the horizontal direction. In example embodiments, the first through electrode 120 may extend through the first substrate 110 and the first insulating interlayer to contact the first wiring structure, and may be electrically connected to the first conductive pad 140 through the first wiring structure.

In example embodiments, the first through electrode 120 may extend through the first substrate 110, the first insulating interlayer and the second insulating interlayer 130, and may contact the first conductive pad 140 to be electrically connected thereto. In some example embodiments, the first through electrode 120 may extend through the first substrate 110, and may contact some of the circuit patterns of the circuit device covered or overlapped by the first insulating interlayer. The first through electrode 120 may be electrically connected to the first conductive pad 140 through some of the circuit patterns and the first wiring structure electrically connected thereto.

The second conductive pad 160 may extend through the third insulating interlayer 150, and may contact the first through electrode 120. Thus, the second conductive pad 160 may be electrically connected to the first conductive pad 140 by the first through electrode 120 and the first wiring structure. In example embodiments, a plurality of second conductive pads 160 may be spaced apart from each other in the horizontal direction.

The first and second conductive pads 140 and 160 may include a metal, e.g., aluminum, copper, nickel, etc., and the first insulating interlayer and the second and third insulating interlayers 130 and 150 may include, e.g., silicon oxide, or a low-k dielectric material such as silicon oxide doped with carbon or fluorine. The wirings and vias included in the first wiring structure may include a conductive material, e.g., a metal, a metal nitride, a metal silicide, etc.

The second semiconductor chip 200 may include a second substrate 210 having first and second surfaces 212 and 214 opposite to each other in the vertical direction, a second through electrode 220 extending through the second substrate 210, a fourth insulating interlayer and a fifth insulating interlayer 230 sequentially stacked in the vertical direction beneath the first surface 212 of the second substrate 210, a third conductive pad 242, a fifth conductive connection member 342 and a fourth conductive pad structure 344 beneath the fifth insulating interlayer 230, a sixth insulating interlayer 250 on the second surface 214 of the second substrate 210, and a fifth conductive pad 260 extending through the sixth insulating interlayer 250.

The second substrate 210 may include a semiconductor material, e.g., silicon, germanium, silicon-germanium, etc., or a III-V group compound semiconductor, e.g., GaP, GaAs, GaSb, etc. In example embodiments, the second substrate 210 may be a SOI substrate or a GOI substrate.

A circuit device, e.g., a volatile memory device such as a DRAM, an SRAM device, etc., or a non-volatile memory device such as a flash memory device, an EEPROM device, etc., may be formed beneath the first surface 212 of the second substrate 210. The circuit device may include circuit patterns, e.g., transistors, capacitors, wiring structures, etc., which may be covered or overlapped by the fourth insulating interlayer.

The fifth insulating interlayer 230 may contain second and third wiring structures 232 and 234 therein. Each of the second and third wiring structures may include, e.g., wirings, vias, etc. FIG. 3 shows each of the second and third wiring structures 232 and 234 includes wirings and vias disposed at three levels, respectively, however, the inventive concept may not be limited thereto.

The third conductive pad 242 and the fourth conductive pad structure 344 may be disposed beneath the fifth insulating interlayer 230, and may contact the second and third wiring structures 232 and 234, respectively, to be electrically connected thereto.

In example embodiments, the fourth conductive pad structure 344 may include a fourth conductive pad 244, a second seed pattern 294 and a second conductive pattern 314 sequentially stacked in the vertical direction downwardly, and a fifth conductive connection member 342 including a first seed pattern 292, a first conductive pattern 312 and a third conductive pattern 332 sequentially stacked in the vertical direction downwardly may be disposed beneath a lower surface of the third conductive pad 242. The fifth conductive connection member 342 may contact the second conductive pad 160 included in the first semiconductor chip 100 to be electrically connected thereto.

In example embodiments, sidewalls of the third and fourth conductive pads 242 and 244 and sidewalls of the first and second seed patterns 292 and 294 may be covered or overlapped by a protective layer 270 beneath the fifth insulating interlayer 230. The protective layer 270 may include a nitride, e.g., silicon nitride. In example embodiments, the protective layer 270 may have a stacked structure including an organic layer containing an oxide and an inorganic layer including a nitride.

Additionally, a portion of a sidewall of the first conductive pattern 312, a portion of a sidewall and a lower surface of the second conductive pattern 314 and a sidewall of the third conductive pattern 332 may be covered or overlapped by the bonding layer 350 beneath the protective layer 270. The bonding layer 350 may include a non-conductive film (NCF), e.g., a thermosetting resin.

A plurality of third conductive pads 242 and a plurality of fourth conductive pads 244 may be spaced apart from each other in the horizontal direction in the second semiconductor chip 200. However, layouts of the third and fourth conductive pads 242 and 244 shown in FIG. 4 is illustrative, and the inventive concept may not be limited thereto.

The third conductive pad 242 may contact the second wiring structure 232 to be electrically connected thereto, and may contact the fifth conductive connection member 342 to be electrically connected thereto. Thus, the third conductive pad 242 may serve as a path for transferring electrical signals between the first and second semiconductor chips 100 and 200. Accordingly, the third conductive pad 242 may also be referred to as a signal pad.

The fourth conductive pad structure 344 may contact the third wiring structure 234 to be electrically connected thereto, however, a lower surface of the fourth conductive pad structure 344 may be covered or overlapped by the bonding layer 350. Thus, the fourth conductive pad structure 344 and the fourth conductive pad 244 included in the fourth conductive pad structure 344 may not serve as a path for transferring electrical signals between the first and second semiconductor chips 100 and 200.

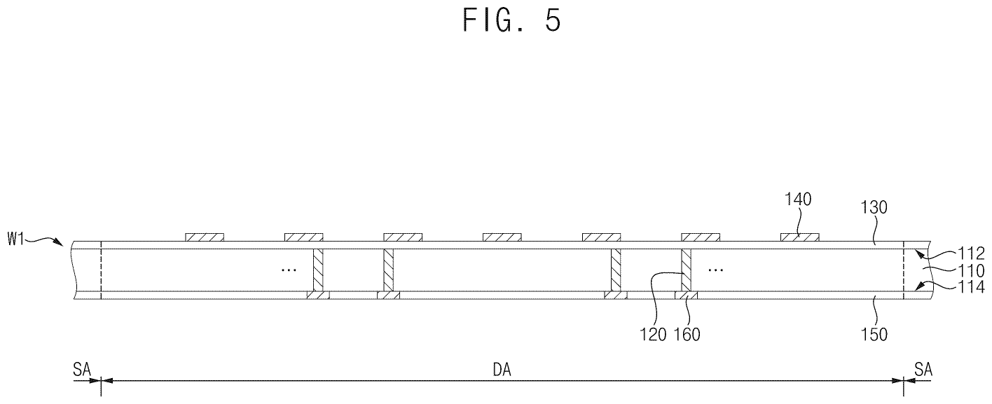

As illustrated below with reference to FIGS. 5 to 15, the fourth conductive pad 244 may be used in an electrical die sorting (EDS) test for the second semiconductor chip 200. Thus, the fourth conductive pad 244 and the fourth conductive pad structure 344 may also be referred to as a test pad and a test pad structure, respectively.

In example embodiments, a lower surface of the third conductive pad 242 may be substantially flat, while a lower surface of the fourth conductive pad 244 may not be flat but uneven. As used herein, an uneven surface may have a non-planar surface, have an irregular surface, have a non-uniform thickness, and/or protruding features. Thus, the lower surface of the fourth conductive pad 244 may not be formed at a uniform height. In example embodiments, a planar area of the fourth conductive pad 244 may be greater than a planar area of the third conductive pad 242.

The second conductive pattern 314 may include an upper portion of which an upper surface and a sidewall may be covered or overlapped by the second seed pattern 294 and a lower portion beneath and contacting the upper portion. An interface between the lower and upper portions of the second conductive pattern 314 may be disposed at substantially the same level or height as a lower surface of the protective layer 270. A sidewall and a lower surface of the lower portion of the second conductive pattern 314 may be covered or overlapped by the bonding layer 350.

In example embodiments, upper and lower surfaces of the second conductive pattern 314, particularly, an upper surface of the upper portion and a lower surface of the lower portion of the second conductive pattern 314 may not be flat but uneven so as not to be disposed at a uniform height. A portion of the second seed pattern 295 between the second conductive pattern 314 and the fourth conductive pad 244, that is, a portion of the second seed pattern 295 between the lower surface of the fourth conductive pad 244 and the upper surface of the second conductive pattern 314 may be curved in the vertical direction so as not to be disposed at a uniform height.

The first conductive pattern 312 may include an upper portion of which an upper surface and a sidewall may be covered or overlapped by the first seed pattern 292 and a lower portion beneath and contacting the upper portion. An interface between the lower and upper portions of the first conductive pattern 312 may be disposed at substantially the same level or height as a lower surface of the protective layer 270. A sidewall of the lower portion of the first conductive pattern 312 may be covered or overlapped by the bonding layer 350. In example embodiments, the upper portion of the first conductive pattern 312 may have a width gradually increasing form a top toward a bottom thereof, and a planar area of the lower portion of the first conductive pattern 312 may be greater than a planar area of the upper portion of the first conductive pattern 312.

Unlike the lower and upper surfaces of the second conductive pattern 314, lower and upper surfaces of the first conductive pattern 312 may be substantially flat, and a portion of the first seed pattern 292 between the first conductive pattern 312 and the third conductive pad 242, that is, a portion of the first seed pattern 292 between the lower surface of the third conductive pad 242 and the upper surface of the first conductive pattern 312 may be curved in the vertical direction so as not to be disposed at a uniform height with respect to the first substrate 110.

A central portion of the third conductive pattern 332 in the vertical direction may have a convex shape, and a sidewall of the third conductive pattern 332 may be covered or overlapped by the bonding layer 350.

In example embodiments, a mean thickness of the fourth conductive pad 244 in the vertical direction may be substantially the same as or similar to a thickness of the third conductive pad 242 in the vertical direction, and a mean thickness of the second conductive pattern 314 in the vertical direction may be substantially the same as or similar to a thickness of the first conductive pattern 312 in the vertical direction. Additionally, the first and second seed patterns 292 and 294 may have substantially the same or similar mean thickness.

Accordingly, a mean thickness in the vertical direction of the fourth conductive pad structure 344 including the fourth conductive pad 244, the second seed pattern 294 and the second conductive pattern 314 sequentially stacked in the vertical direction may be substantially the same as or similar to a mean thickness in the vertical direction of a stacked structure including the third conductive pad 242, the first seed pattern 292 and the first conductive pattern 312 sequentially stacked in the vertical direction.

As a result, a first mean distance from a lower surface of the fifth insulating interlayer 230 to a lower surface of the fourth conductive pad structure 344 may be substantially the same as or similar to a second distance from the lower surface of the fifth insulating interlayer 230 to a lower surface of the stacked structure, and a difference between the first mean distance and the second distance may be a difference between a distance from the lower surface of the fifth insulating interlayer 230 to a lower surface of the fifth conductive connection member 342 and a thickness of the third conductive pattern 332 in the vertical direction.

Thus, as illustrated below with reference to FIGS. 5 to 15, a lower surface of the bonding layer 350 covering or overlapping the fourth conductive pad structure 344 and the fifth conductive connection member 342 may have a constant height, and no gap may be formed between the bonding layer 350 under the second semiconductor chip 200 and the third insulating interlayer 150 of the first semiconductor chip 100 contacting the bonding layer 350.

In example embodiments, a distance from the lower surface of the fifth insulating interlayer 230 to a lowermost surface of the fourth conductive pad structure 344 may be greater than a distance from the lower surface of the fifth insulating interlayer 230 to the lower surface of the stacked structure. That is, the lowermost surface of the fourth conductive pad structure 344 may be lower than the lower surface of the stacked structure, and may be higher than the lower surface of the fifth conductive connection member 342.

In example embodiments, a distance from the lower surface of the fifth insulating interlayer 230 to a lowermost surface of the fourth conductive pad 244 may be greater than a distance from the lower surface of the fifth insulating interlayer 230 to a lower surface of the third conductive pad 242. That is, the lowermost surface of the fourth conductive pad 244 may be lower than the lower surface of the third conductive pad 242.

The second through electrode 220 may extend in the second substrate 210 in the vertical direction, and a plurality of second through electrodes 220 may be spaced apart from each other in the horizontal direction. In example embodiments, the second through electrode 220 may extend through the second substrate 210 and the fourth insulating interlayer to contact the second wiring structure 232, and may be electrically connected to the third conductive pad 242 through the second wiring structure 232.

In example embodiments, the second through electrode 220 may extend through the second substrate 210, the fourth insulating interlayer and the fifth insulating interlayer 230, and may contact the third conductive pad 242 to be electrically connected thereto. In example embodiments, the second through electrode 220 may extend through the second substrate 210, and may contact some of the circuit patterns of the circuit device covered or overlapped by the fourth insulating interlayer. The second through electrode 220 may be electrically connected to the third conductive pad 242 through some of the circuit patterns and the second wiring structure 232 electrically connected thereto.

The fifth conductive pad 260 may extend through the sixth insulating interlayer 250, and may contact the second through electrode 220. Thus, the fifth conductive pad 260 may be electrically connected to the third conductive pad 242 by the second through electrode 220 and the second wiring structure 232. In example embodiments, a plurality of fifth conductive pads 260 may be spaced apart from each other in the horizontal direction.

Each of the third to fifth conductive pads 242, 244 and 260 may include a metal, e.g., aluminum, copper, nickel, etc., each of the first and second conductive patterns 312 and 314 may include a metal, e.g., copper, aluminum, tungsten, nickel, molybdenum, gold, silver, chromium, tin, titanium, etc.

Each of the first and second seed patterns 292 and 294 may include, e.g., titanium/copper, nickel/gold, titanium/palladium, titanium/nickel, chromium/copper or an alloy thereof, and the third conductive pattern 332 may include, e.g., tin, tin/silver, tin/copper, tin/indium, tin/silver/copper, etc.

The second through electrode 220 and the wirings and the vias included in the second and third wiring structures 232 and 234 may include a conductive material, e.g., a metal, a metal nitride, a metal silicide, etc., and the fourth insulating interlayer and the fifth and sixth insulating interlayers 230 and 250 may include, e.g., silicon oxide, or a low-k dielectric material, e.g., an oxide doped with carbon or fluorine.

The third to fifth semiconductor chips 300, 400 and 500 may be sequentially stacked on the second semiconductor chip 200, and the bonding layer 350 may be interposed between neighboring ones of the third to fifth semiconductor chips 300, 400 and 500. No gap may be formed between the bonding layer 350 and a corresponding one of the third to fifth semiconductor chips 300, 400 and 500 under the bonding layer 350.

Each of the third to fifth semiconductor chips 300, 400 and 500 may have a structure substantially the same as or similar to that of the second semiconductor chip 200, and thus repeated explanations are omitted herein.

The third semiconductor chip 300 may include a third substrate 310 having first and second surfaces 312 and 314 opposite to each other in the vertical direction, the fourth semiconductor chip 400 may include a fourth substrate 410 having first and second surfaces 412 and 414 opposite to each other in the vertical direction, and the fifth semiconductor chip 500 may include a fifth substrate 510 having first and second surfaces 512 and 514 opposite to each other in the vertical direction.

The second through electrode 220 may extend through each of the third and fourth substrates 310 and 410, the fourth insulating interlayer and the fifth insulating interlayer 230 may be sequentially stacked in the vertical direction beneath each of the first surfaces 312, 412 and 512 of a corresponding one of the third, fourth and fifth substrates 310, 410 and 510, the third conductive pad 242, the fifth conductive connection member 342 and the fourth conductive pad structure 344 may be disposed beneath the fifth insulating interlayer 230, and the sixth insulating interlayer 250 and the fifth conductive pad 260 extending through the sixth insulating interlayer 250 may be disposed on each of the second surfaces 314 and 414 of a corresponding one of the third and fourth substrates 310 and 410.

Each of the third to fifth substrates 310, 410 and 510 may include a semiconductor material, e.g., silicon, germanium, silicon-germanium, etc., or a III-V group compound semiconductor, e.g., GaP, GaAs, GaSb, etc. In example embodiments, each of the third to fifth substrates 310, 410 and 510 may be a SOI substrate or a GOI substrate.

A circuit device, e.g., a volatile memory device such as a DRAM, an SRAM device, etc., or a non-volatile memory device such as a flash memory device, an EEPROM device, etc., may be formed beneath each of the first surfaces 312, 412 and 512 of a corresponding one of the third, fourth and fifth substrates 310, 410 and 510. The circuit device may include circuit patterns, e.g., transistors, capacitors, wiring structures, etc., which may be covered or overlapped by the fourth insulating interlayer.

The first to fifth semiconductor chips 100, 200, 300, 400 and 500 may be electrically connected to each other by the first and second through electrodes 120 and 220 extending through the second to fourth substrates 210, 310 and 410, the first wiring structure and the second wiring structure 232 electrically connected to the first and second through electrodes 120 and 220, the first, second, third and fifth conductive pads 140, 160, 242 and 260 electrically connected to the first wiring structure and the second wiring structure 232, and the fifth conductive connection member 342 electrically connected to the first, second, third and fifth conductive pads 140, 160, 242 and 260, and may communicate data signals and control signals with each other.

The molding member 600 may cover or overlap sidewalls of the second to fifth semiconductor chips 200, 300, 400 and 500 on the first semiconductor chip 100, and an upper surface of the molding member 600 may be substantially coplanar with an upper surface of the fifth semiconductor chip 500. The molding member 600 may include polymer, e.g., epoxy molding compound (EMC).

As illustrated above, the bonding layer 350 that may bond the first to fifth semiconductor chips 100, 200, 300, 400 and 500 with each other may be formed with no gap therebetween, and thus the first to fifth semiconductor chips 100, 200, 300, 400 and 500 sequentially stacked may be well bonded, so that the HBM package including the first to fifth semiconductor chips 100, 200, 300, 400 and 500 may have enhanced electrical characteristics.

Hereinafter, a method of manufacturing the semiconductor package of FIG. 2 is illustrated.

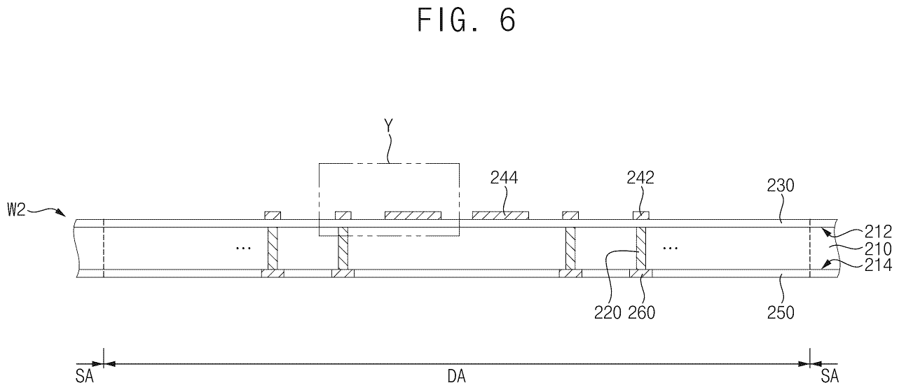

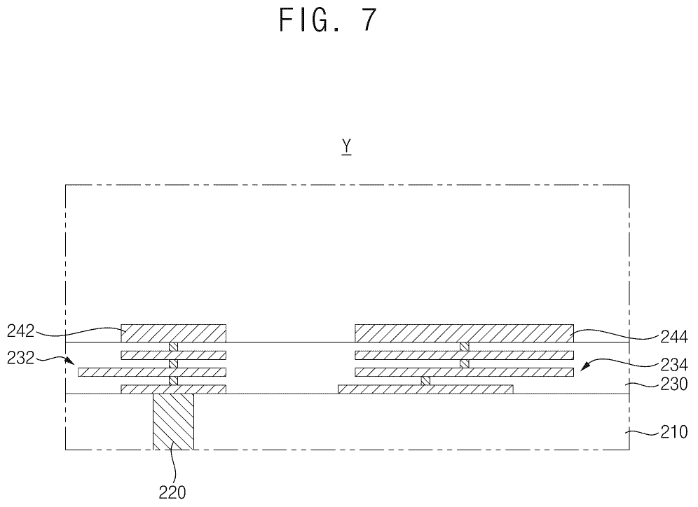

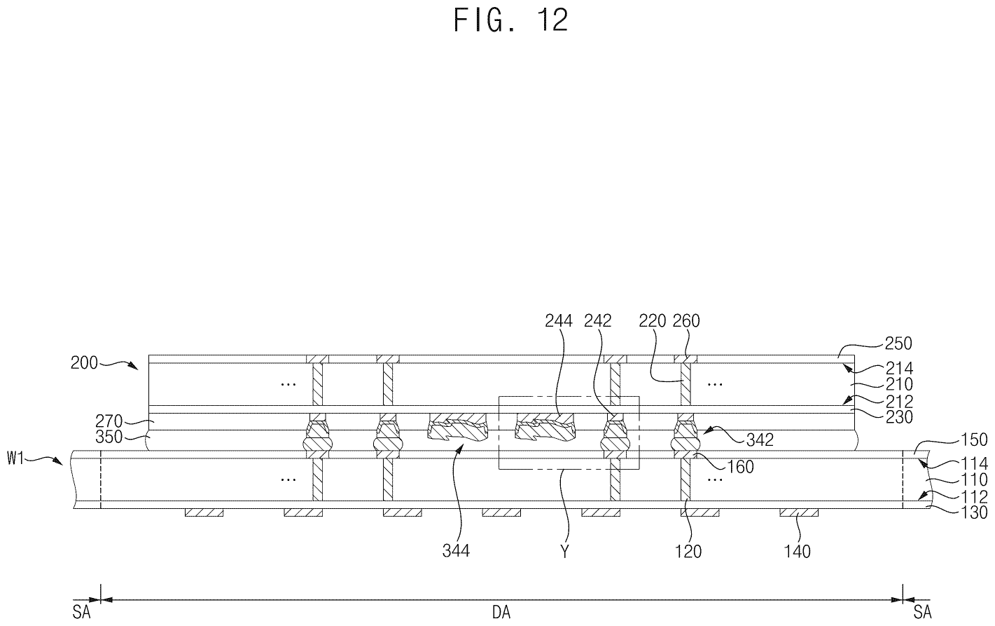

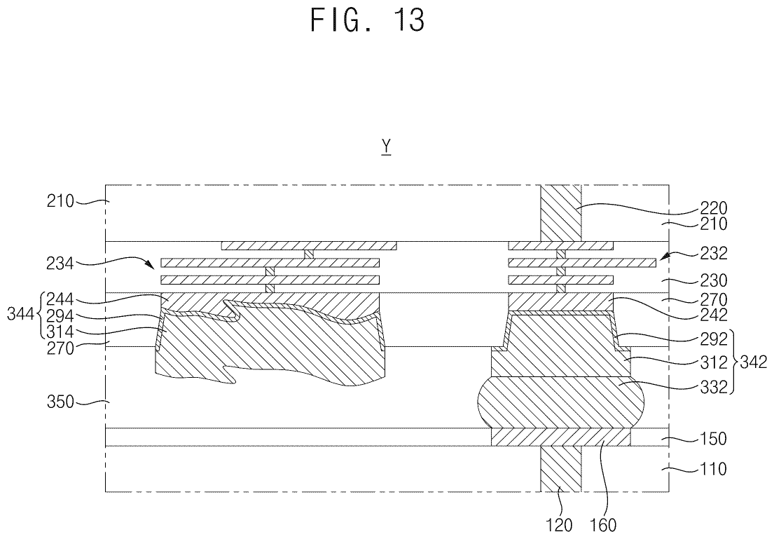

FIGS. 5 to 15 are cross-sectional views illustrating a method of manufacturing an HBM package in accordance with example embodiments. FIGS. 7 to 11 are enlarged cross-sectional views of region Y of FIG. 6, and FIG. 13 is an enlarged cross-sectional view of region Y of FIG. 12.

Referring to FIG. 5, a first wafer W1 may be provided.

In example embodiments, the first wafer W1 may include a first substrate 110 having first and second surfaces 112 and 114 opposite to each other in the vertical direction. Additionally, the first wafer W1 may include a plurality of die regions DA and a scribe lane region SA surrounding the die region DA, and the first wafer W1 may be cut by a sawing process along the scribe lane region SA to be singulated into a plurality of first semiconductor chips in respective die regions DA.

In the die region DA, a circuit device may be formed on the first surface 112 of the first substrate 110. In example embodiments, the circuit device may include a logic device. The circuit device may include circuit patterns, e.g., transistors, capacitors, wiring structures, etc., and a first insulating interlayer may be formed on the first surface 112 of the first substrate 110 to cover or overlap the circuit patterns.

A second insulating interlayer 130 may be formed on the first insulating interlayer, and may contain first wiring structure. The first wiring structure may include, e.g., wirings, vias, etc.

A first conductive pad 140 may be formed on the second insulating interlayer 130, and may contact the first wiring structure to be electrically connected thereto. In example embodiments, a plurality of first conductive pads 140 may be spaced apart from each other in the horizontal direction.

In example embodiments, a first through electrode 120 may extend through the first substrate 110. In example embodiments, a plurality of first through electrodes 120 may be spaced apart from each other in the horizontal direction.

A third insulating interlayer 150 may be formed beneath or on the second surface 114 of the first substrate 110, and a second conductive pad 160 may be formed through the third insulating interlayer 150 to contact the first through electrode 120. In example embodiments, a plurality of second conductive pads 160 may be spaced apart from each other in the horizontal direction.

Referring to FIGS. 6 and 7, a second wafer W2 may be provided.

In example embodiments, the second wafer W2 may include a second substrate 210 having first and second surfaces 212 and 214 opposite to each other in the vertical direction. Additionally, the second wafer W2 may include a plurality of die regions DA and a scribe lane region SA surrounding the die region DA, and the second wafer W2 may be cut by a sawing process along the scribe lane region SA to be singulated into a plurality of second semiconductor chips in respective die regions DA.

In the die region DA, a circuit device may be formed on the first surface 212 of the second substrate 210. In example embodiments, the circuit device may include a volatile memory device, e.g., a DRAM device, an SRAM device, etc., or a non-volatile memory device, e.g., a flash memory device, an EEPROM device, etc. The circuit device may include circuit patterns, e.g., transistors, capacitors, wiring structures, etc., and a fourth insulating interlayer may be formed on the first surface 212 of the second substrate 210 to cover or overlap the circuit patterns.

A fifth insulating interlayer 230 may be formed on the fourth insulating interlayer, and may contain second and third wiring structures 232 and 234. Each of the second and third wiring structures may include, e.g., wirings, vias, etc.

Third and fourth conductive pads 242 and 244 may be formed on the fifth insulating interlayer 230, and may contact the second and third wiring structures 232 and 234 to be electrically connected thereto. In example embodiments, an upper surface of each of the third and fourth conductive pads 242 and 244 may be substantially flat, and the upper surfaces of the third and fourth conductive pads 242 and 244 may be disposed at substantially the same height. In an example embodiment, a planar area of the fourth conductive pad 244 may be greater than a planar area of the third conductive pad 242 in a plan view.

In example embodiments, a second through electrode 220 may extend through the second substrate 210.

A sixth insulating interlayer 250 may be formed beneath the second surface 214 of the second substrate 210, and a fifth conductive pad 260 may be formed through the sixth insulating interlayer 250 to contact the second through electrode 220. In example embodiments, a plurality of fifth conductive pads 260 may be spaced apart from each other in the horizontal direction.

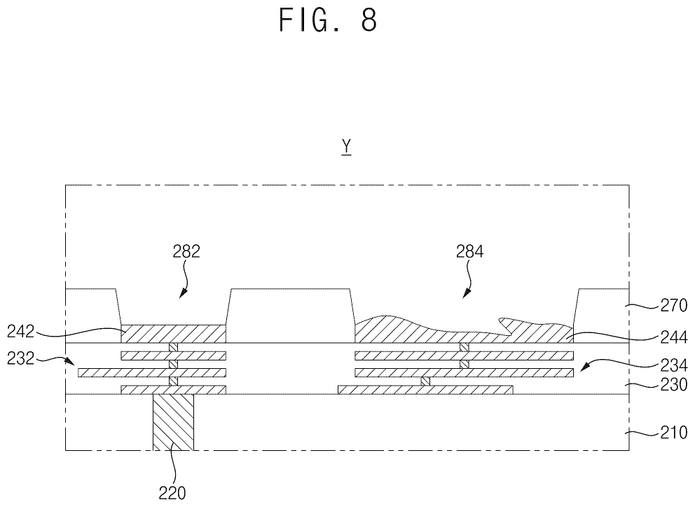

Referring to FIG. 8, a protective layer 270 may be formed on the fifth insulating interlayer 230 to cover or overlap the third and fourth conductive pads 242 and 244, and may be partially removed to form first and second openings 282 and 284 exposing upper surfaces of the third and fourth conductive pads 242 and 244, respectively.

A wafer test may be performed on the second semiconductor chips in the second wafer W2, and whether the second semiconductor chips are good or not is determined. In example embodiments, the wafer test may be performed by contacting a probe included in a probe card with upper surfaces of the fourth conductive pads 244 in each of the second semiconductor chips. Thus, after the wafer test, an indentation may remain on the upper surface of each of the fourth conductive pads 244 so that the upper surface of each of the fourth conductive pads 244 may be uneven.

However, the upper surfaces of the third and fourth conductive pads 242 and 244 may be substantially coplanar with each other, and thus a mean height of the upper surfaces of the fourth conductive pads 244 may be substantially the same as or similar to a height of the upper surface of the third conductive pad 242. In example embodiments, an uppermost surface of the fourth conductive pad 244 may be higher than the upper surface of the third conductive pad 242.

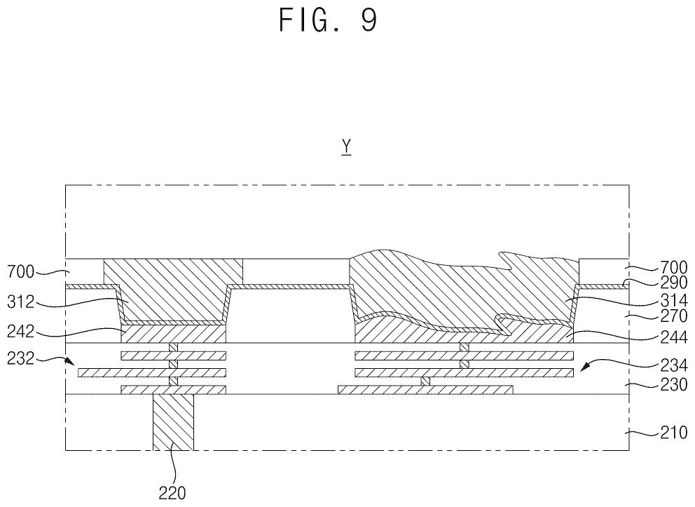

Referring to FIG. 9, a seed layer 290 may be conformally formed on the protective layer 270 and the third and fourth conductive pads 242 and 244 exposed by the first and second openings 282 and 284, respectively, a first photoresist layer may be formed on the seed layer 290, and the first photoresist layer may be patterned to form a first photoresist pattern 700.

In example embodiments, the first photoresist pattern 700 may include third and fourth openings exposing upper surfaces of portions of the seed layer 290 overlapping the first and second openings 282 and 284, respectively, in the vertical direction.

In example embodiments, the third opening may expose not only the portion of the seed layer 290 overlapping the first opening 282 in the vertical direction, but also a portion of the seed layer 290 adjacent thereto in the horizontal direction, that is, a portion of the seed layer 290 on an upper surface of the first photoresist pattern 700.

The seed layer 290 may be formed by, e.g., a sputtering process.

For example, an electroplating process may be performed to form first and second conductive patterns 312 and 314 in the third and fourth openings, respectively. Each of the first and second conductive patterns 312 and 314 may include a lower portion substantially coplanar with or lower than an upper surface of the protective layer 270, and an upper portion contacting the lower portion and higher than the upper surface of the protective layer 270. In example embodiments, an upper surface of the upper portion of the first conductive pattern 312 may have an area greater than an area of the lower portion of the first conductive pattern 312.

In example embodiments, the first conductive pattern 312 may have a substantially flat upper surface, while the second conductive pattern 314 may have an uneven upper surface corresponding to the upper surface of the second conductive pad 244, and thus the upper surface of the second conductive pattern 314 may not be formed at a uniform height with respect to substrate 210. A mean thickness of the second conductive pattern 314 in the vertical direction may be substantially the same as a thickness of the first conductive pattern 312 in the vertical direction, and thus a mean height of the upper surface of the second conductive pattern 314 may be substantially the same as or similar to a height of the upper surface of the first conductive pattern 312. In example embodiments, an uppermost surface of the second conductive pattern 314 may be higher than the upper surface of the first conductive pattern 312.

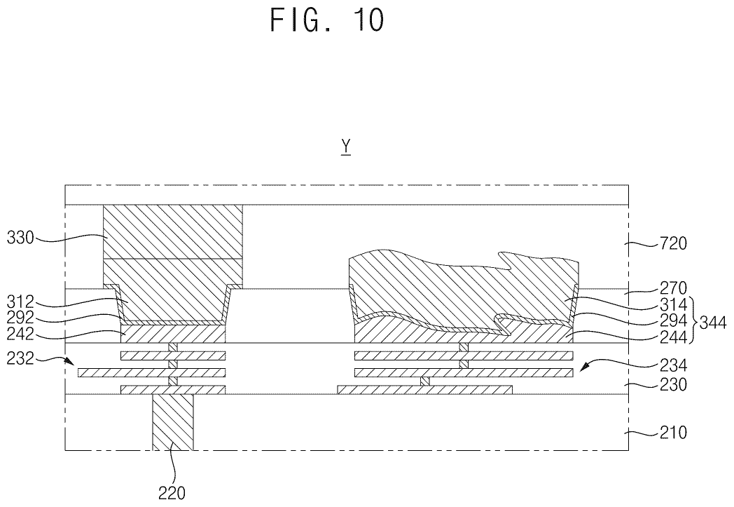

Referring to FIG. 10, for example, a stripping process may be performed to remove the first photoresist pattern 700 so that a portion of the seed layer 290 may be exposed, and the exposed portion of the seed layer 290 may be removed to form first and second seed patterns 292 and 294 on inner walls of the third and fourth openings, respectively, which may cover or overlap lower surfaces and sidewalls of the first and second conductive patterns 312 and 314, respectively.

The fourth conductive pad 244, the second seed pattern 294 and the second conductive pattern 314 sequentially stacked in the vertical direction may collectively form a fourth conductive pad structure 344. A mean height of an upper surface of the fourth conductive pad structure 344 may be substantially the same as or similar to a height of an upper surface of a stacked structure including the third conductive pad 242, the first seed pattern 292 and the first conductive pattern 312. In example embodiments, an uppermost surface of the fourth conductive pad structure 344 may be higher than the upper surface of the stacked structure.

A second photoresist layer may be formed on the protective layer 270 to cover or overlap the first and second conductive patterns 312 and 314, and may be patterned to form a second photoresist pattern 720. In example embodiments, the second photoresist pattern 720 may include a fifth opening exposing an upper surface of the first conductive pattern 312.

In example embodiments, an electroplating process may be performed to form a preliminary third conductive pattern 330 in the fifth opening. In some embodiments, the preliminary third conductive pattern 330 may be formed by a screen printing process or a deposition process.

In example embodiments, the preliminary third conductive pattern 330 may have a flat upper surface.

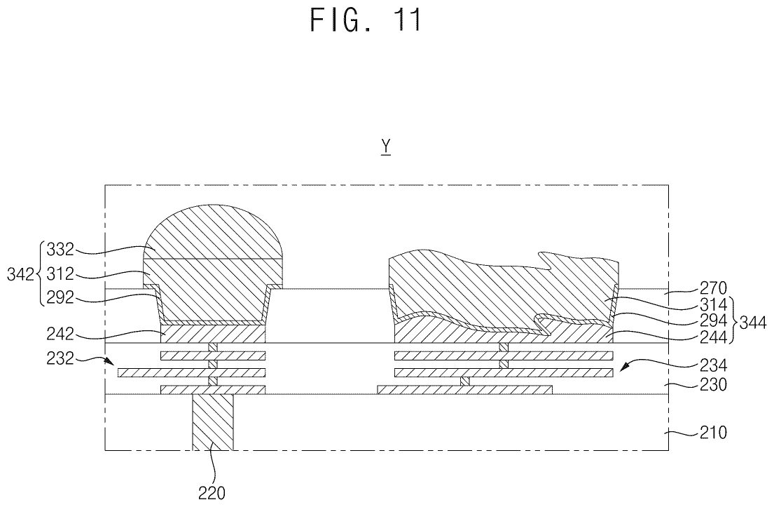

Referring to FIG. 11, for example, a stripping process may be performed to remove the second photoresist pattern 720, and a reflow process may be performed so that the preliminary third conductive pattern 330 may be transformed into a third conductive pattern 332.

In example embodiments, the third conductive pattern 332 may have a hemispherical shape or a half-oval shape.

The first seed pattern 292, the first conductive pattern 312 and the third conductive pattern 332 sequentially stacked on the third conductive pad 242 may collectively form a fifth conductive connection member 342. A height of an upper surface of the fifth conductive connection member 342 may have a difference from a mean height of an upper surface of the fourth conductive pad structure 344 by a thickness of the third conductive pattern 332 in the vertical direction.

Referring to FIGS. 12 and 13, the second wafer W2 may be cut by a sawing process along the scribe lane region SA to be singulated into a plurality of second semiconductor chips 200, and a bonding layer 350 may be bonded to each second semiconductor chip 200 that has been determined to be good.

The bonding layer 350 may be formed on the protective layer 270 to cover or overlap the fifth conductive connection member 342 and the fourth conductive pad structure 344. The bonding layer 350 may include an NCF such as thermosetting resin.

In some embodiments, the bonding layer 350 may be formed on the protective layer 270 of the second wafer W2, before performing the sawing process.

As illustrated above, the height of the upper surface of the fifth conductive connection member 342 may have a difference from the height of the upper surface of the fourth conductive pad structure 344 only by the thickness of the third conductive pattern 332, and thus heights of the respective portions of the bonding layer 350 covering or overlapping the fifth conductive connection member 342 and the fourth conductive pad structure 344 may have only small difference on the fifth conductive connection member 342 and the fourth conductive pad structure 344.

If the fourth conductive pad structure 344 does not include the second conductive pattern 314 and the second seed pattern 294 but includes the fourth conductive pad 244, the height of the fifth conductive connection member 342 may have difference from the height of the upper surface of the fourth conductive pad structure 344 by sum of the thickness of the third conductive pattern 332 and the thicknesses of the first conductive pattern 312 and the first seed pattern 292, and thus the heights of the respective portions of the bonding layer 350 covering or overlapping the fifth conductive connection member 342 and the fourth conductive pad structure 344 may have a large difference on the fifth conductive connection member 342 and the fourth conductive pad structure 344.

After overturning the first wafer W1 so that the second surface 114 may face upwardly, and overturing each of the second semiconductor chips 200 so that the second surface 214 may face upwardly, each of the second semiconductor chips 200 may be mounted on the first wafer W1 by contacting the bonding layer 350 of each of the second semiconductor chips 200 with an upper surface of the third insulating interlayer 150 of the first wafer W1. The second semiconductor chips 200 may be disposed on the die regions DA, respectively, of the first wafer W1, and the fifth conductive connection member 342 may contact an upper surface of the second conductive pad 160 of the first semiconductor chip.

For example, a thermal compression bonding (TCB) process may be performed at a temperature of equal to or less than about 400° C. so that the second semiconductor chips 200 may be bonded with the first wafer W1. During the TCB process, the NCF included in the bonding layer 350 may be melted to have fluidity, and may flow between each of the second semiconductor chips 342 and the first wafer W1. The NCF may flow and be cured between the fifth conductive connection members 342, and may fill a space between the fifth conductive connection members 342. A portion of the cured bonding layer 350 may protrude in the horizontal direction from a sidewall of the second semiconductor chip 200.

By the TCB process, the fifth conductive connection member 342 of the second semiconductor chip 200 may be bonded with the second conductive pad 160 of the first semiconductor chip.

As illustrated above, there is not a big height difference between the upper surfaces of the portions of the bonding layer 350 on the fifth conductive connection member 342 and the fourth conductive pad structure 344, respectively, and thus the bonding layer 350 having fluidity by the TCB process may fill a space between the fifth conductive connection members 342, particularly, a space between the fourth conductive pad structure 344 and the third insulating interlayer 150 of the first semiconductor chip, so that no gap may be formed therebetween.

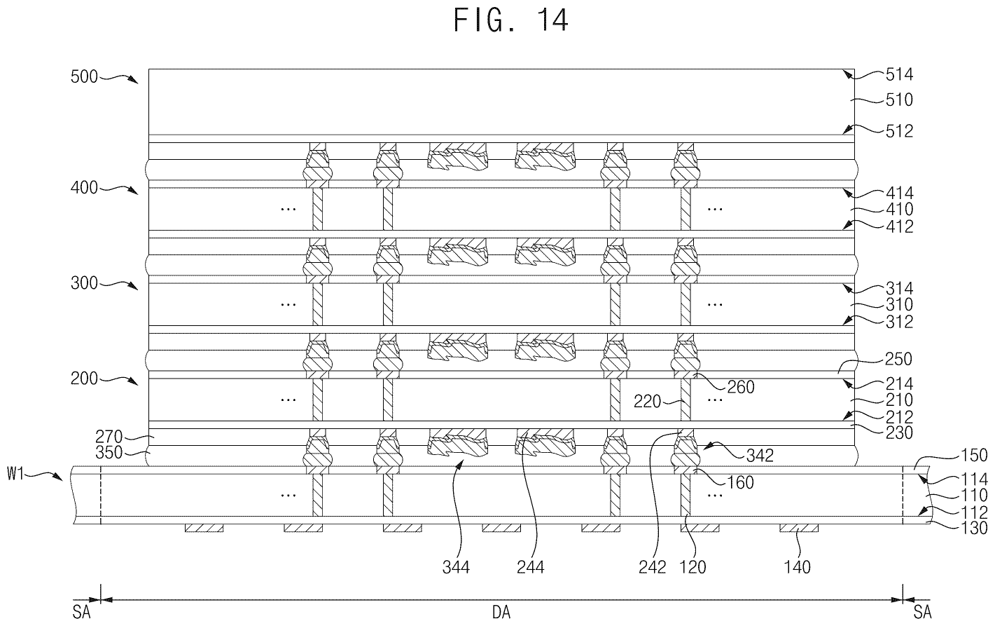

Referring to FIG. 14, third to fifth semiconductor chips 300, 400 and 500 may be sequentially stacked on the second semiconductor chip 200.

Particularly, processes substantially the same as or similar to those illustrated with respect to FIGS. 6 to 13 may be performed to provide a singulated third semiconductor chip 300, and processes substantially the same as or similar to those illustrated with respect to FIGS. 12 and 13 may be performed so that the third semiconductor chip 300 may be mounted on the second semiconductor chip 200.

In example embodiments, the third semiconductor chip 300 may include a third substrate 310 having first and second surfaces 312 and 314 opposite to each other in the vertical direction, and may be mounted on the second semiconductor chip 200 so that the bonding layer 350 beneath the first surface 312 of the third substrate 310 may contact the sixth insulating interlayer 250 on the second surface 214 of the second substrate 210. The fifth conductive connection member 342 of the third semiconductor chip 300 may be bonded with the fifth conductive pad 260 of the second semiconductor chip 300.

Likewise, the fourth semiconductor chip 400 including a fourth substrate 410 having first and second surfaces 412 and 414 opposite to each other in the vertical direction may be mounted on the third semiconductor chip 300, and the fifth semiconductor chip 500 including a fifth substrate 510 having first and second surfaces 512 and 514 opposite to each other in the vertical direction may be mounted on the fourth semiconductor chip 400.

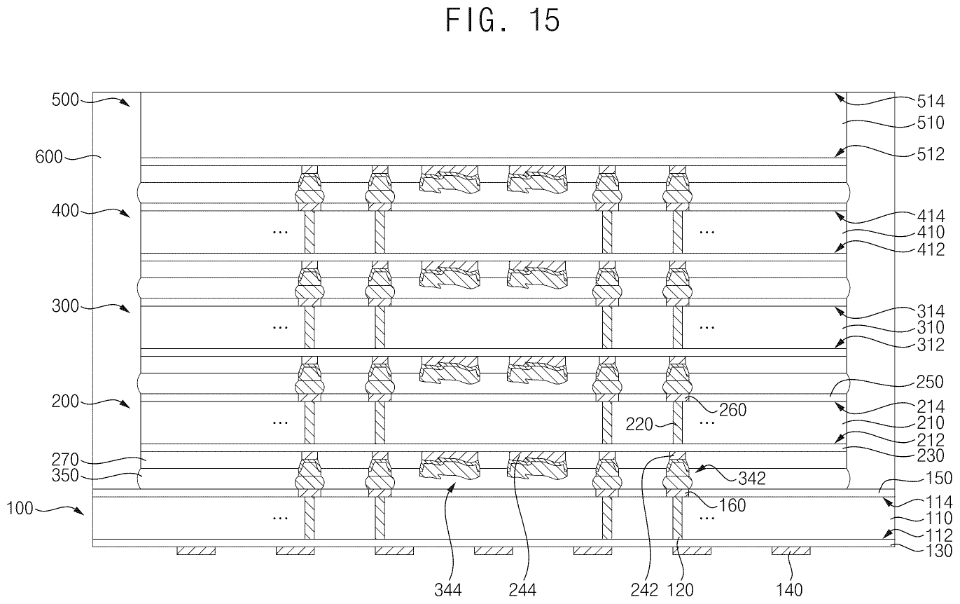

Referring to FIG. 15, a molding member 600 may be formed on the first wafer W1 to cover or overlap the second to fifth semiconductor chips 200, 300, 400 and 500.

In example embodiments, the molding member 600 may expose an upper surface of the fifth semiconductor chip 500.

Referring to FIG. 2 again, after forming a fourth conductive connection member 52 to contact a lower surface of the first conductive pad 140 beneath the second insulating interlayer 130 of the first wafer W1, the first wafer W1 may be cut by, e.g., a sawing process along the scribe lane region SA to be singulated into a plurality of first semiconductor chips 100.

During the sawing process, the molding member 600 may also be cut, and may cover or overlap the second to fifth semiconductor chips 200, 300, 400 and 500 on each of the singulated first semiconductor chips 100.

By the above processes, the HBM package may be manufactured. As illustrated above, the bonding layer 350 that may bond the first to fifth semiconductor chips 100, 200, 300, 400 and 500 with each other may be formed with no gap therebetween, and thus the first to fifth semiconductor chips 100, 200, 300, 400 and 500 may be well bonded with each other so that the HBM package may have enhanced electrical characteristics.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package comprising:
a buffer die;
memory dies sequentially stacked on the buffer die;
a bonding layer that extends between ones of the memory dies, wherein the bonding layer is configured to bond ones of the memory dies with each other; and
a molding member on the buffer die, wherein the molding member is on sidewalls of the memory dies,
wherein each of the memory dies includes:
a substrate having first and second surfaces opposite to each other in a vertical direction substantially perpendicular to an upper surface of the buffer die; and
a first signal pad and a test pad structure on the first surface of the substrate,
wherein the test pad structure includes a test pad and a first conductive pattern stacked in the vertical direction on the first surface of the substrate, and
wherein the first conductive pattern has an uneven surface facing the substrate.

2. The semiconductor package according to claim 1, wherein the test pad has an uneven surface facing the substrate.

3. The semiconductor package according to claim 1, wherein an upper surface of the test pad is substantially coplanar with an upper surface of the first signal pad.

4. The semiconductor package according to claim 3, wherein a distance from the substrate to a lowermost surface of the test pad is less than a distance from the substrate to a lower surface of the first signal pad.

5. The semiconductor package according to claim 1, wherein a distance from the substrate to a lowermost surface of the test pad structure is less than a distance from the substrate to a lower surface of the first signal pad.

6. The semiconductor package according to claim 1, further comprising:
a conductive connection member in contact with the first signal pad,
wherein the conductive connection member includes a second conductive pattern and a third conductive pattern stacked on a lower surface of the first signal pad.

7. The semiconductor package according to claim 6, wherein a distance from the substrate to a lowermost surface of the first conductive pattern is less than a distance from the substrate to a lower surface of the second conductive pattern.

8. The semiconductor package according to claim 6, wherein a distance from the substrate to a lowermost surface of the first conductive pattern is greater than a distance from the substrate to a lower surface of the third conductive pattern.

9. The semiconductor package according to claim 6, wherein each of the memory dies further includes a second signal pad on the second surface of the substrate,
wherein the conductive connection member contacts the second signal pad of a memory die among the memory dies that is directly under a memory die having the conductive connection member among the memory dies.

10. The semiconductor package according to claim 1, wherein each of the memory dies further includes an insulating interlayer on the first surface of the substrate,
wherein the insulating interlayer comprises first and second wiring structures therein, and
wherein the test pad and the first signal pad are electrically connected to the first and second wiring structures, respectively.

11. The semiconductor package according to claim 1, wherein the test pad structure further includes a seed pattern between the first conductive pattern and the test pad, and
wherein the first conductive pattern includes a first portion and a second portion,
wherein an upper surface and a sidewall of the first portion is overlapped by the seed pattern, and a lower surface and a sidewall of the second portion is overlapped by the bonding layer.

12. The semiconductor package according to claim 1, wherein the bonding layer and each of the memory dies is free of a gap therebetween.

13. A semiconductor package comprising:
a buffer die;
memory dies sequentially stacked on the buffer die;
a conductive connection member between the memory dies, the conductive connection member including a first conductive pattern and a second conductive pattern stacked in a vertical direction substantially perpendicular to an upper surface of the buffer die, and the first and second conductive patterns including different materials from each other;
a bonding layer between the memory dies, wherein the bonding layer is configured to bond ones of the memory dies with each other; and
a molding member on the buffer die, wherein the molding member is on sidewalls of the memory dies,
wherein each of the memory dies includes:
a substrate having first and second surfaces opposite to each other in the vertical direction; and
a signal pad and a test pad structure on the first surface of the substrate,
wherein the test pad structure includes a test pad and a third conductive pattern stacked in the vertical direction on the first surface of the substrate,
wherein the signal pad contacts the first conductive pattern of the conductive connection member, and
wherein a distance from the substrate to a lowermost surface of the third conductive pattern is less than a distance from the substrate to a lower surface of the first conductive pattern.

14. The semiconductor package according to claim 13, wherein portions of a lower surface of the third conductive pattern have different respective distances from the substrate.

15. The semiconductor package according to claim 13, wherein portions of a lower surface of the test pad have different respective distances from the substrate.

16. The semiconductor package according to claim 13, wherein a distance from the substrate to a lowermost surface of the test pad is less than a distance from the substrate to a lower surface of the signal pad.

17. The semiconductor package according to claim 13, wherein each of the memory dies further includes an insulating interlayer on the first surface of the substrate,
wherein the insulating interlayer comprises first and second wiring structures therein, and
wherein the test pad and the signal pad are electrically connected to the first and second wiring structures, respectively.

18. A semiconductor package comprising:
a first die;
a second die on the first die;
a conductive connection member between the first and second dies, the conductive connection member including first and second conductive patterns stacked in a vertical direction substantially perpendicular to an upper surface of the first die, and the first and second conductive patterns including different materials from each other; and
a bonding layer between the first and second dies, wherein the bonding layer is configured to bond the first and second dies with each other and is on sidewalls of the conductive connection member,
wherein the first die includes a first substrate having first and second surfaces opposite to each other in the vertical direction,
wherein the second die includes:
a second substrate having first and second surfaces opposite to each other in the vertical direction; and
a signal pad and a test pad structure on the first surface of the second substrate,
wherein the test pad structure includes a test pad and a third conductive pattern stacked in the vertical direction on the first surface of the second substrate,
wherein the third conductive pattern has an uneven lower surface, and
wherein the signal pad contacts the conductive connection member and the first conductive pattern, and
wherein distance from the first substrate to a lowermost surface of the third conductive pattern is less than distance from the first substrate to a lower surface of the first conductive pattern.

19. The semiconductor package according to claim 18, wherein the first and third conductive patterns include substantially a same material.

20. The semiconductor package according to claim 18, wherein the first die includes a logic device, and the second die includes a memory device.
